(19) United States
(12) Patent Application Publication
(10) Pub. No.: US 2012/0055708 A1
(43) Pub. Date: Mar. 8, 2012

(54) ELECTRONIC COMPONENT PACKAGE SEALING MEMBER, ELECTRONIC COMPONENT PACKAGE, AND METHOD FOR PRODUCING THE ELECTRONIC COMPONENT PACKAGE SEALING MEMBER

(75) Inventor: Naoki KOHDA, Kakogawa-shi (JP)

(73) Assignee: DAISHINKU CORPORATION, Kakogawa-shi (JP)

(21) Appl. No.: 13/220,845

(22) Filed: Aug. 30, 2011

(30) Foreign Application Priority Data
Sep. 7, 2010 (JP) 2010-200243

(51) Int. Cl. H05K 1/11; H01K 3/10

(52) U.S. Cl. 174/264; 29/852

(57) ABSTRACT

An electronic component package includes a first sealing member and a second sealing member. The first sealing member has one principal surface on which an electronic component element is to be mounted. The second sealing member is opposite the first sealing member. The second sealing member hermetically encloses an electrode of the electronic component element. A through hole passes through between one principal surface and another principal surface of a substrate constituting the first sealing member. A conducting material fills the through hole. A resin material seals an open end portion of the through hole at a side of the other principal surface of the substrate.

### CROSS-REFERENCE TO RELATED APPLICATIONS

The present application claims priority under 35 U.S.C. 119(a) to Japanese Patent Application No. 2010-200243, filed Sep. 7, 2010. The contents of this application are herein incorporated by reference in their entirety.

### BACKGROUND OF THE INVENTION

1. Field of the Invention

The present invention relates to an electronic component package sealing member that can be used as a first sealing member of an electronic component package in which an electrode of an electronic component element is sealed with the first sealing member and a second sealing member that are arranged so as to oppose each other. The present invention also relates to an electronic component package that uses the electronic component package sealing member and to a method for producing the electronic component package sealing member.

2. Discussion of the Background

The packages of electronic components (hereinafter referred to as electronic component packages) such as piezoelectric resonator devices have their internal spaces hermetically enclosed in order to prevent property degradation of the electrodes of the electronic component elements mounted in the internal spaces.

An electronic component package of this kind includes two sealing members such as a base and a lid. The base and the lid define a package in the form of a rectangular parallelepiped. In the internal space of the package, an electronic component element such as a piezoelectric resonator plate is bonded to and held by the base. The bonding of the base and the lid hermetically encloses the electrodes of the electronic component element in the internal space of the package.

For example, Japanese Unexamined Patent Application Publication No. 6-283951 (hereinafter referred to as Patent Citation PLT 1) discloses a crystal part (an electronic component of the present invention) that includes a package defined by the base and the lid. In the internal space of the package, a crystal plate is hermetically enclosed. The crystal part includes a base that has a through hole passing through the substrate of the base. The through hole includes, on its internal surface, a wiring metal made of a multiple-layer metal film such as Cr—Ni—Au. The through hole further includes an alloy such as Au—Ge welded therein, thus securing air tightness of the internal space of the package.

Incidentally, electronic components are heated when mounted on boards such as printed circuit boards. Unfortunately, in the crystal part disclosed in PLT 1, the heat applied to the crystal part when mounted on the board can cause softening (diffusion) of the boundary between the internal surface of the through hole and the alloy attached to the internal surface, degrading the adherence between the alloy and the internal surface of the through hole. The degraded adherence of the alloy causes detachment of the alloy off the internal surface of the through hole, and the detached alloy can drop outside the package of the crystal part. The degradation of the adherence or the dropping of the alloy out of the through hole leads to degraded air tightness of the internal space of package. Thus, the crystal part of PLT 1 may not ensure sufficient air tightness of the internal space of the package after mounted on a printed circuit board.

### SUMMARY OF THE INVENTION

The present invention has been made in view of the above-described circumstances, and it is an object of the present invention to provide an electronic component package sealing member that, when used as a sealing member of an electronic component package, minimizes the degradation of air tightness of the internal space of the electronic component package, and to provide a method for producing the electronic component package sealing member.

It is another object of the present invention to provide an electronic component package that minimizes the degradation of air tightness of the internal space of the electronic component package.

According to one aspect of the present invention, an electronic component package sealing member can be used as a first sealing member of an electronic component package. The electronic component package includes the first sealing member and a second sealing member. The first sealing member has one principal surface on which an electronic component element is to be mounted. The second sealing member is opposite the first sealing member and hermetically encloses an electrode of the electronic component element. The electronic component package sealing member includes a substrate, a conducting material, and a resin material. The substrate constitutes the electronic component package sealing member. The substrate includes at least one through hole passing through between one principal surface and another principal surface of the substrate. The conducting material is in the at least one through hole. The resin material seals an open end portion of the at least one through hole at a side of the other principal surface of the substrate.

With this configuration, at least one through hole passes through between one principal surface and the other principal surface of the electronic component package sealing member. The open end portion of the at least one through hole at the side of the other principal surface (the surface opposite the mounting surface on which the electronic component element is mounted) is sealed with a resin material. This minimizes detachment of the conducting material filling the at least one through hole and minimizes dropping of the conducting material out of the at least one through hole. Additionally, the resin material sealing the open end portion of the at least one through hole at the side of the other principal surface blocks heat conduction from the other principal surface of the electronic component package sealing member to the conducting material filling the at least one through hole. This minimizes degradation of the adherence between the conducting material and the substrate constituting the electronic component package sealing member, in spite of, for example, heat associated with mounting of the electronic component package on the board. This in turn minimizes degradation of air tightness in the internal space of the electronic component package.

The electronic component package sealing member according to the one aspect of the present invention may further include a seed film on an internal surface of the at least one through hole. A filling layer may be plated on a surface of the seed film. The filling layer may include the conducting material.

This configuration facilitates productivity of the electronic component package sealing member. Specifically, the seed film formation on the at least one through hole and the plating on the filling layer are collectively executable with respect to a plurality of through holes by a sheet method, thus ensuring high productivity. Use of the conducting material constituting the filling layer as a material of the seed film improves the adherence between the seed film and the conducting material, that is, improves the adherence of the conducting material with respect to the electronic component package sealing member.

The electronic component package sealing member according to the one aspect of the present invention may further include a resin pattern sealing the open end portion of the at least one through hole. The resin pattern may include a photosensitive resin material.

In this configuration, the resin pattern made of a photosensitive resin material is easily and precisely formed on the open end portion of the at least one through hole at the side of the other principal surface by photolithography or a like method. The resin pattern securely seals the open end portion of the at least one through hole at the side of the other principal surface. Thus, the resin pattern more securely minimizes the dropping of the conducting material out of the at least one through hole.

According to another aspect of the present invention, an electronic component package includes a first sealing member and a second sealing member. The first sealing member has one principal surface on which an electronic component element is to be mounted. The first sealing member is the electronic component package sealing member according to the one aspect of the present invention. The second sealing member is opposite the first sealing member. The second sealing member hermetically encloses an electrode of the electronic component element.

With this configuration, the electronic component package sealing member according to the one aspect of the present invention is used as the first sealing member. This minimizes dropping of the conducting material filling the at least one through hole of the electronic component package sealing member out of the at least one through hole. Additionally, the resin material sealing the open end portion of the at least one through hole at the side of the other principal surface blocks heat conduction from the other principal surface of the electronic component package sealing member to the conducting material filling the at least one through hole. This minimizes degradation of the adherence between the conducting material and the substrate constituting the electronic component package sealing member, in spite of, for example, heat associated with mounting of the electronic component package on the board. This in turn minimizes degradation of air tightness in the internal space of the electronic component package.

According to another aspect of the present invention, a method is for producing an electronic component package sealing member that can be used as a first sealing member of an electronic component package. The electronic component package includes the first sealing member and a second sealing member. The first sealing member has one principal surface on which an electronic component element is to be mounted. The second sealing member is opposite the first sealing member. The second sealing member hermetically encloses an electrode of the electronic component element. The method includes forming at least one through hole passing through between one principal surface and another principal surface of a substrate constituting the electronic component package sealing member. The at least one through hole is filled with a conducting material. An open end portion of the at least one through hole at a side of the other principal surface of the substrate is sealed with a resin material.

With this method, at least one through hole passes through between one principal surface and the other principal surface of the substrate constituting the electronic component package sealing member. The open end portion of the at least one through hole at the side of the other principal surface is sealed with a resin material. This ensures production of an electronic component package sealing member that minimizes detachment of the conducting material filling the at least one through hole and minimizes dropping of the conducting material out of the at least one through hole. Additionally, with the electronic component package sealing member produced by this method, the resin material sealing the open end portion of the at least one through hole at the side of the other principal surface blocks heat conduction from the other principal surface of the electronic component package sealing member to the conducting material filling the at least one through hole. This minimizes degradation of the adherence between the conducting material and the substrate constituting the electronic component package sealing member, in spite of, for example, heat associated with mounting of the electronic component package on the board. Accordingly this method ensures production of an electronic component package sealing member that minimizes degradation of air tightness in the internal space of the electronic component package.

The method according to the other aspect of the present invention may further include forming a seed film on an internal surface of the at least one through hole. The filling step may include plating a filling layer on a surface of the seed film. The filling layer may include the conducting material.

This method improves the productivity of the electronic component package sealing member. Specifically, the seed film formation on the at least one through hole and the plating on the filling layer are collectively executable with respect to a plurality of through holes by a sheet method, thus improving the productivity. Use of the conducting material constituting the filling layer as a material of the seed film improves the adherence between the seed film and the conducting material, that is, improves the adherence of the conducting material with respect to the substrate constituting the electronic component package sealing member.

In the method according to the other aspect of the present invention, the sealing step may include forming a resin pattern to seal the open end portion of the at least one through hole by photolithography using the resin material. The resin material may have photosensitivity.

With this method, the resin pattern is easily and precisely formed by photolithography using a resin material having photosensitivity. This, as a result, ensures hermetic enclosure of the open end portion of the at least one through hole at the side of the exterior of the electronic component package.

### BRIEF DESCRIPTION OF THE DRAWINGS

FIG. 1 is a schematic cross-sectional view of a crystal resonator according to an embodiment of the present invention taken along the line A-A of a base shown in FIG. 2, for schematically illustrating an internal space of the crystal resonator.

FIG. 2 is a schematic plan view of the base according to the embodiment of the present invention.

FIG. 3 is a schematic rear view of the base according to the embodiment of the present invention.

FIG. 4 is a schematic cross-sectional view of a through hole portion of the base shown in FIG. 1.

FIG. 5 is a schematic rear view of a lid according to the embodiment of the present invention.

FIG. 6 is a schematic plan view of a crystal resonator plate according to the embodiment of the present invention.

FIG. 7 is a schematic partial cross-sectional view of a wafer in a step of a production process of the base according to the embodiment of the present invention.

FIG. 8 is a schematic partial cross-sectional view of the wafer in a step of the production process of the base according to the embodiment of the present invention.

FIG. 9 is a schematic partial cross-sectional view of the wafer in a step of the production process of the base according to the embodiment of the present invention.

FIG. 10 is a schematic partial cross-sectional view of the wafer in a step of the production process of the base according to the embodiment of the present invention.

FIG. 11 is a schematic partial cross-sectional view of the wafer in a step of the production process of the base according to the embodiment of the present invention.

FIG. 12 is a schematic partial cross-sectional view of the wafer in a step of the production process of the base according to the embodiment of the present invention.

FIG. 13 is a schematic partial cross-sectional view of the wafer in a step of the production process of the base according to the embodiment of the present invention.

FIG. 14 is a schematic partial cross-sectional view of the wafer in a step of the production process of the base according to the embodiment of the present invention.

FIG. 15 is a schematic partial cross-sectional view of the wafer in a step of the production process of the base according to the embodiment of the present invention.

FIG. 16 is a schematic partial cross-sectional view of the wafer in a step of the production process of the base according to the embodiment of the present invention.

FIG. 17 is a schematic partial cross-sectional view of the wafer in a step of the production process of the base according to the embodiment of the present invention.

FIG. 18 is a schematic partial cross-sectional view of the wafer in a step of the production process of the base according to the embodiment of the present invention.

FIG. 19 is a schematic partial cross-sectional view of the wafer in a step of the production process of the base according to the embodiment of the present invention.

FIG. 20 is a schematic partial cross-sectional view of the wafer in a step of the production process of the base according to the embodiment of the present invention.

FIG. 21 is a schematic partial cross-sectional view of the wafer in a step of the production process of the base according to the embodiment of the present invention.

FIG. 22 is a schematic partial cross-sectional view of the wafer in a step of the production process of the base according to the embodiment of the present invention.

FIG. 23 is a schematic partial cross-sectional view of the wafer in a step of the production process of the base according to the embodiment of the present invention.

FIG. 24 is a schematic partial cross-sectional view of the wafer in a step of the production process of the base according to the embodiment of the present invention.

FIG. 25 is a schematic partial cross-sectional view of the wafer in a step of the production process of the base according to the embodiment of the present invention.

FIG. 26 is a schematic partial cross-sectional view of the wafer in a step of the production process of the base according to the embodiment of the present invention.

FIG. 27 is a schematic partial cross-sectional view of the wafer in a step of the production process of the base according to the embodiment of the present invention.

FIG. 28 is a schematic partial cross-sectional view of the wafer in a step of the production process of the base according to the embodiment of the present invention.

FIG. 29 is a schematic cross-sectional view of a base according to another embodiment, for schematically illustrating a part of the through hole corresponding to FIG. 4.

FIG. 30 is a schematic cross-sectional view of a base according to another embodiment, for schematically illustrating a part of the through hole corresponding to FIG. 4.

FIG. 31 is a schematic cross-sectional view of a base according to another embodiment.

FIG. 32 is a schematic plan view of a crystal resonator plate according to another embodiment.

### DESCRIPTION OF THE EMBODIMENTS

Embodiments of the present invention will be described below by referring to the accompanying drawings. In the following embodiments, the present invention is applied to a package of a crystal resonator, which is a piezoelectric resonator device, as an electronic component package. The present invention is also applied to a tuning-fork crystal resonator plate, which is a piezoelectric resonator plate, as an electronic component element.

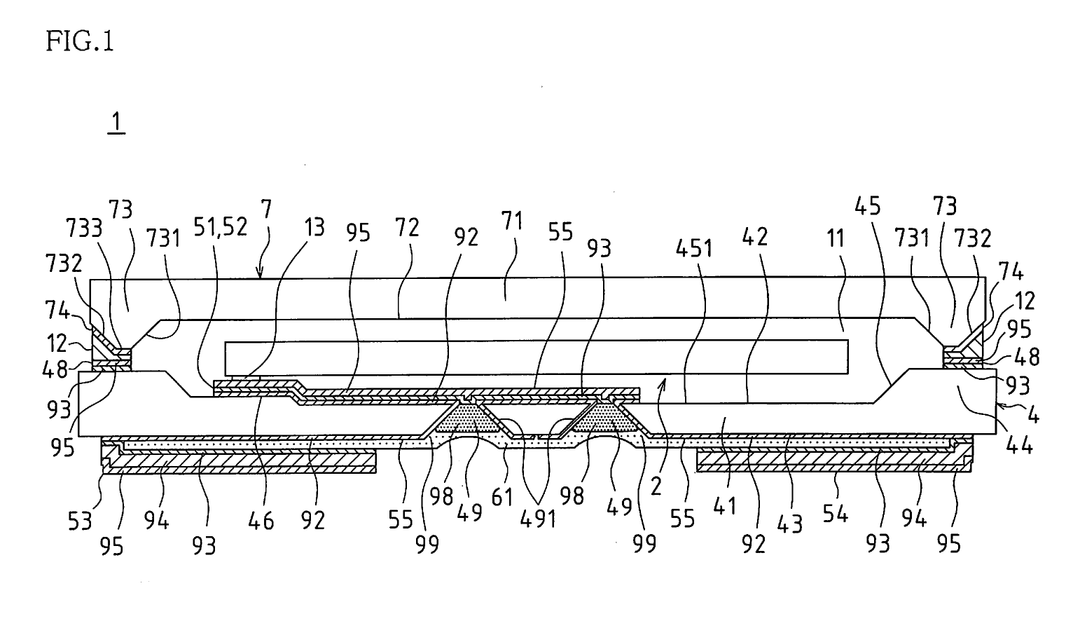

As shown in FIG. 1, the crystal resonator 1 according to this embodiment of the present invention includes a crystal resonator plate 2 (an electronic component element of the present invention), a base 4 (an electronic component package sealing member as a first sealing member of the present invention), and a lid 7 (a second sealing member of the present invention). The crystal resonator plate 2 is made of a tuning-fork crystal resonator plate. The base 4 holds and hermetically encloses the crystal resonator plate 2. The lid 7 is disposed opposite the base 4 and hermetically encloses driving electrodes 31 and 32 (electrodes of the electronic component element of the present invention) of the crystal resonator plate 2 held on the base 4.

In the crystal resonator 1, the base 4 and the lid 7 are bonded to each other with a bonding material 12 made of a Au—Sn alloy, a first bonding layer 48 described below, and a second bonding layer 74 described below. The bonding results in a main casing defining a hermetically enclosed internal space 11. In the internal space 11, the crystal resonator plate 2 is electrically and mechanically bonded to the base 4 by ultrasonic bonding of Flip Chip Bonding (FCB) with a conductive bump 13 such as gold bump. In this embodiment, the conductive bump 13 used is a bump plating made of a non-liquid member such as a gold bump.

Next, the constituents of the crystal resonator 1 will be described below.

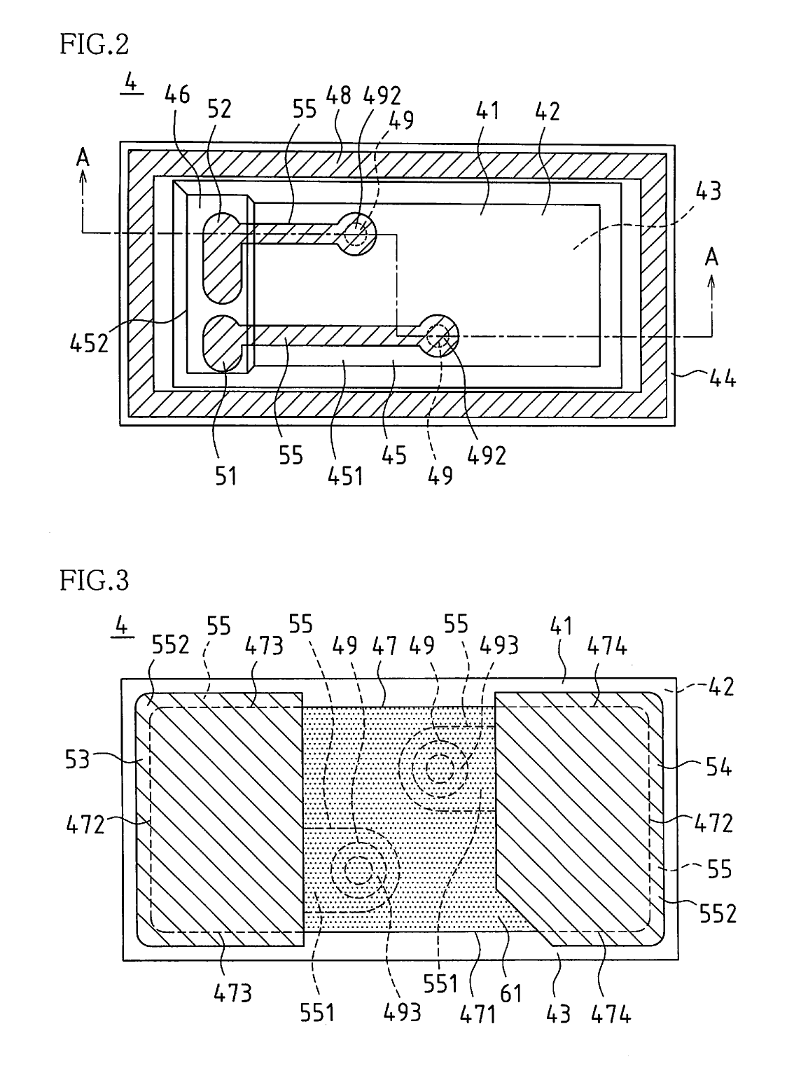

The base 4 is made of glass material such as borosilicate glass. As shown in FIGS. 1 to 3, the base 4 is in the form of a box including a bottom portion 41 and a wall portion 44 that extends upward from the bottom portion 41 along an outer periphery of one principal surface 42 of the base 4. To form the base 4 into this box shape, a substrate of a rectangular parallelepiped single plate is wet etched.

The internal surface of the wall portion 44 of base 4 has a tapered shape. The wall portion 44 has a top face serving as a bonding face for the lid 7, and the bonding face has a first bonding layer 48 for bonding with the lid 7. The first bonding layer 48 has a multiple-layer structure that includes: a sputtering film (see reference numeral 92 in FIG. 1) formed on the top face of the wall portion 44 of the base 4 by sputtering; and a plated film (see reference numeral 95 in FIG. 1) plated on the sputtering film. The sputtering film includes a Ti film (not shown) formed on the top face of the wall portion 44 of the base 4 by sputtering and a Au film (not shown) formed on the Ti film by sputtering. The plated film includes a Au film plated n the sputtering film.

The base 4 includes, on its one principal surface 42, a cavity 45 having a rectangular shape in plan view surrounded by the bottom portion 41 and the wall portion 44. The cavity 45 includes, on its bottom face 451, a pedestal portion 46 etched over the entire one end portion 452 in a longer side direction. The crystal resonator plate 2 is mounted on the pedestal portion 46. The wall face of the cavity 45 is the internal surface of the wall portion 44 and tapered as described above.

The base 4 includes a pair of electrode pads 51 and 52, external terminal electrodes 53 and 54, and a wiring pattern 55. The electrode pads 51 and 52 are electrically and mechanically coupled to the driving electrodes 31 and 32, respectively, of the crystal resonator plate 2. The external terminal electrodes 53 and 54 are electrically coupled to an external part or an external device. The wiring pattern 55 electrically couples the electrode pad 51 to the external terminal electrode 54, and electrically couples the electrode pad 52 to the external terminal electrode 53. The electrode pads 51 and 52, the external terminal electrodes 53 and 54, and the wiring pattern 55 constitute an electrode 5 of the base 4. The electrode pads 51 and 52 are disposed on the surface of the pedestal portion 46. The two external terminal electrodes 53 and 54 are disposed on both sides of the other principal surface 43 of the base 4 and separated from one another in the longer side direction.

The electrode pads 51 and 52 include a first seed film on a substrate of the base 4 (see reference numeral 92 in FIG. 1), a second seed film on the first seed film (see reference numeral 93 in FIG. 1), and a plated film on the second seed film (see reference numeral 95 in FIG. 1). The first seed film constituting the electrode pads 51 and 52 includes a Ti film (not shown) and a Cu film (not shown). The Ti film is formed on the one principal surface 42 of the base 4 by sputtering. The Cu film is formed on the Ti film by sputtering. The second seed film (see reference numeral 93 in FIG. 1) includes a Ti film (not shown) formed on the first seed film by sputtering and a Au film (not shown) formed on the Ti film by sputtering. The plated film (see reference numeral 95 in FIG. 1) includes a Au film plated on the second seed film.

The wiring pattern 55 is formed from the one principal surface 42 of the base 4 to the other principal surface 43 of the base 4 via an internal surface 491 of through holes 49 (see below) such that the electrode pads 51 and 52 are electrically coupled to the external terminal electrodes 53 and 54. The wiring pattern 55 includes a first seed film (see reference numeral 92 in FIG. 1) on the substrate of the base 4. The second seed film (see reference numeral 93 in FIG. 1) and the plated film (see reference numeral 95 in FIG. 1) are disposed on a part of the first seed film (see reference numeral 92 in FIG. 1) located at the one principal surface 42 of the base 4. The first seed film (see reference numeral 92 in FIG. 1) constituting the wiring pattern 55 includes a Ti film (not shown) formed on the one principal surface 42 of the base 4 by sputtering and a Cu film (not shown) formed on the Ti film by sputtering. The second seed film (see reference numeral 93 in FIG. 1) includes a Ti film (not shown) formed on the first seed film by sputtering and a Au film (not shown) formed on the Ti film by sputtering. The plated film (see reference numeral 95 in FIG. 1) includes a Au film plated on the second seed film. It is noted that for viewability of the schematic cross-sectional view shown in FIG. 1, gaps are omitted between: a part of the wiring pattern 55 coupling the electrode pad 52 and the external terminal electrode 53 on the one principal surface 42 of the base 4; and another part of the wiring pattern 55 coupling the electrode pad 51 and the external terminal electrode 54 on the one principal surface 42 of the base 4. Similar omissions are made in the other schematic cross-sectional views and the schematic partial cross-sectional views.

The external terminal electrodes 53 and 54 includes a seed film (see reference numeral 93 in FIG. 1), first plated film (see reference numeral 94 in FIG. 1), and second plated film (see reference numeral 95 in FIG. 1). The seed film is disposed on the resin pattern 61 (see below) and on the wiring pattern 55 (see reference numeral 92 in FIG. 1) on the other principal surface 43 of the base 4. The first plated film (see reference numeral 94 in FIG. 1) is disposed on the seed film (see reference numeral 93 in FIG. 1). The second plated film (see reference numeral 95 in FIG. 1) is disposed on the first plated film. The seed film (see reference numeral 93 in FIG. 1) constituting the external terminal electrodes 53 and 54 includes a Ti film (not shown) and a Au film (not shown) formed on the Ti film by sputtering. The Ti film is formed on the resin pattern 61 and the wiring pattern 55 (see reference numeral 92 in FIG. 1) on the other principal surface 43 of the base 4 by sputtering. The first plated film (see reference numeral 94 in FIG. 1) includes a Ni film plated on the seed film, and the second plated film (see reference numeral 95 in FIG. 1) includes a Au film plated on the first plated film.

As shown in FIGS. 1 to 4, the base 4 includes the through holes 49 through which the driving electrodes 31 and 32 of the crystal resonator plate 2 are conducted from inside the cavity 45 to outside the cavity 45 by the wiring pattern 55 via the electrode pads 51 and 52.

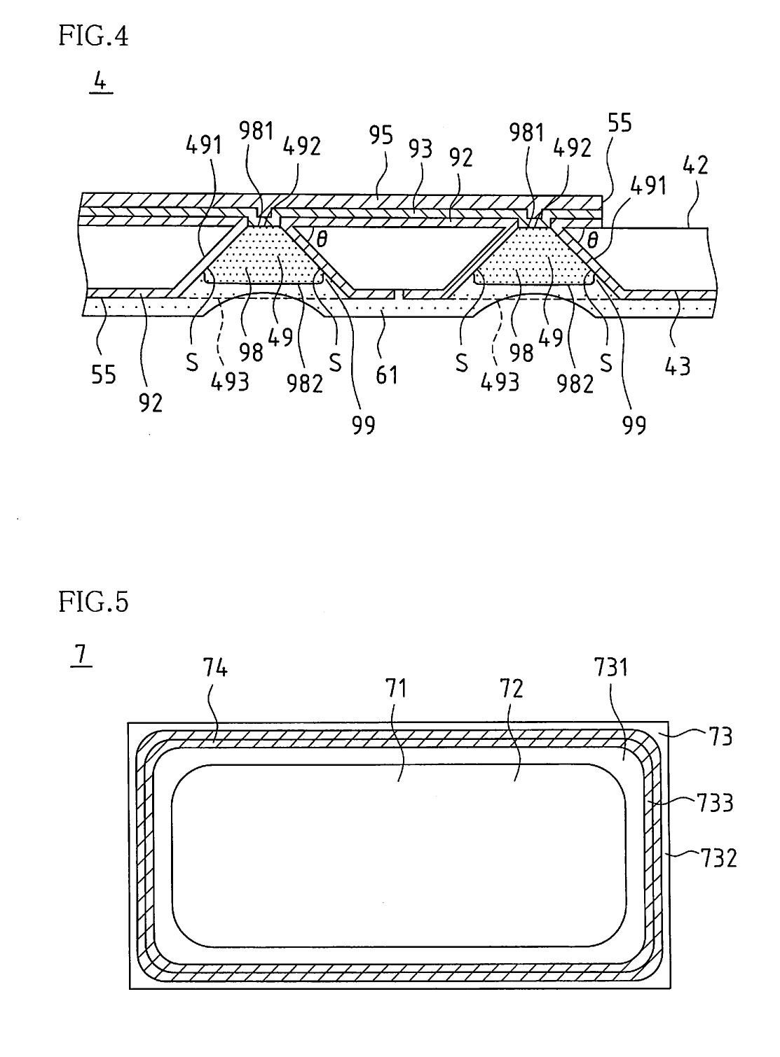

The through holes 49 are simultaneously formed with the cavity 45 at the time of etching of the base 4 by photolithography. As shown in FIGS. 1 to 4, the base 4 has two through holes 49 passing through between both principal surfaces 42 and 43 of the base 4. The through holes 49 have internal surfaces 491 that are inclined relative to the one principal surface 42 and the other principal surface 43 of the base 4, thus having tapered shapes. As shown in FIG. 4, the diameter of each through hole 49 is maximum at its other end opening face 493 at the side of the other principal surface 43 of the base 4 and minimal at one end opening face 492 at the side of the one principal surface 42 of the base 4. Thus, in this embodiment, the internal surfaces 491 of the through holes 49 are inclined relative to the one principal surface 42 and the other principal surface 43 of the base 4 such that the angle defined by the one principal surface 42 of the base 4 and the internal surface 491 of each through hole 49 (see reference numeral θ in FIG. 4) is set at approximately 45 degrees. This, however, should not be construed in a limiting sense. For example, the angle defined by the one principal surface 42 of the base 4 and the internal surface 491 of each through hole 49 (see reference numeral θ in FIG. 4) may be more than 45 degrees, specifically 70 to 90 degrees. If the angle defined by the one principal surface 42 of the base 4 and the internal surface 491 of each through hole 49 (see reference numeral θ in FIG. 4) approaches 90 degrees, the through holes 49 occupy a smaller area on the base 4, which provides a greater freedom of choice on where to form the wiring pattern 55.

The internal surfaces 491 of the through holes 49 each include a first seed film (see reference numeral 92 in FIG. 1) made of Ti and Cu as a part of the wiring pattern 55. The through holes 49 are filled with infills (conducting materials of the present invention) made of Cu on the first seed film (see reference numeral 92 in FIG. 1). The infills form infill layers 98 to seal the through holes 49. The infill layers 98 are made of Cu plated layers formed by electrolytic plating on the surface of the first seed film. As shown in FIG. 4, the infill layers 98 each have one end face 981 at the side of the one principal surface 42 of the base 4. The one end face 981 is in flush with the one principal surface 42 of the base 4.

Each through hole 49 has an open end portion at the side of the other principal surface 43 of the base 4 (an open end portion at the side of the other end opening face 493). The open end portion is sealed with a resin pattern 61 made of a photosensitive resin material.

The resin pattern 61 is disposed on the other principal surface 43 of the base 4. As shown in FIG. 3, the other principal surface 43 of the base 4 has a resin pattern formed area 47 on which the resin pattern 61 is formed. The resin pattern formed area 47 has an approximately rectangular shape defined by longer sides 471 along the longer side direction of the other principal surface 43 and shorter sides 472 along the shorter side direction of the other principal surface 43. The resin pattern formed area 47 encompasses the other end opening faces 493 of the through holes 49. The resin pattern 61 formed on the resin pattern formed area 47 seals the open end portions of the through holes 49 at the side of the other end opening face 493, and coats the wiring pattern 55 disposed on periphery portions 551 of the other end opening faces 493 of the through holes 49. Thus, the resin pattern 61 seals the open end portions of the through holes 49, which are filled with the infill layers 98, on the side of the other end opening faces 493. This improves a sealing strength of the through holes 49.

As shown in FIG. 4, parts of the resin pattern 61 contact the infill layers 98 inside the through holes 49. Specifically, the deposition plating at the time of electrolytic plating of the infill layer 98 makes a convex shape on the other end portion (an end portion at the other end face 982 side of the infill layer 98) of each infill layer 98 at the side of the other principal surface 43 of the base 4. As shown in FIG. 4, this creates gaps 99 between: the seed film (see reference numeral 92 in FIG. 4) formed at end portions of the internal surfaces 491 of the through holes 49 at the side of the other principal surface 43; and the other end portion of the infill layer 98. A resin material constituting the resin pattern 61 enters the gaps 99 to provide an anchor effect, which ensures the adherence among the resin pattern 61, the infill layer 98, and the internal surface 491 of the through holes 49 (see reference numeral 92 indicative of the seed film in FIG. 4).

A part of the wiring pattern 55 at the side of the other principal surface 43 of the base 4 avoids being coated by the resin pattern 61. Specifically, the part of the wiring pattern 55 is disposed at an area 552 that is a periphery of the resin pattern formed area 47 in plan view, along both end portions 473 and 474 of the longer sides 471 and the shorter sides 472 of the resin pattern formed area 47 (see FIG. 3). The external terminal electrodes 53 and 54 are disposed on the wiring pattern 55 on the area 552, which is the periphery of the resin pattern formed area 47 in plan view, and on the resin pattern 61. Specifically, the wiring pattern 55 and the external terminal electrodes 53 and 54 are disposed as if to sandwich the end portions of the resin pattern 61. Disposing the wiring pattern 55, the external terminal electrodes 53 and 54, and the resin pattern 61 in this manner improves the adhesion strength of the resin pattern 61 on the base 4 and improves the strength of the resin pattern 61.

A resin material constituting the resin pattern 61 uses polybenzoxazole (PBO). The resin material constituting the resin pattern 61 is not limited to polybenzoxazole (PBO). It is also possible to use any resin material that has satisfactory adherence with respect to the material constituting the base 4 (such as glass material). Examples of the resin material constituting the resin pattern 61 include benzocyclobutene (BCB), epoxy, polyimide, and fluororesin. The resin material constituting the resin pattern 61 in the embodiment, namely, polybenzoxazole (PBO), is a photosensitive resin material that ensures pattern formation by photolithography. As used herein, the term photosensitive resin material broadly encompasses a photosensitive resin composition containing a photosensitizing agent and a resin, as well as a resin material made of a photosensitive resin.

The lid 7 is made of a glass material such as borosilicate glass. As shown in FIGS. 1 and 5, the lid 7 includes a top portion 71 and a wall portion 73 that extends from the top portion 71 downwardly along the outer periphery of one principal surface 72. To form such lid 7, a substrate of a rectangular parallelepiped single plate is wet etched.

Both side faces of the wall portion 73 of the lid 7 (an internal surface 731 and an outer surface 732) each have a tapered shape. The wall portion 73 has a second bonding layer 74 to be bonded with the base 4.

As shown in FIG. 1, the second bonding layer 74 of the lid 7 extends over a top face 733 and the outer surface 732 of the wall portion 73 of the lid 7. The second bonding layer 74 has a multiple-layer structure of a Ti film (not shown) made of Ti and a Au film (not shown) made of Au on the Ti film. The Ti film and the Au film are formed by sputtering.

The bonding material 12 bonds the base 4 and the lid 7, and is layered on the second bonding layer 74 of the lid 7. The bonding material 12 has a multiple-layer structure of a Au/Sn film (not shown) made of Au/Sn alloy plated on the second bonding layer 74 of the lid 7 and a Au film (not shown) plated on the Au/Sn film. The Au film has a multiple-layer structure of a Au strike plated film and a Au plated film plated on the Au strike plated film. In the bonding material 12, the Au/Sn film is melted by heat melting into a Au/Sn alloy film. The bonding material 12 may be a Au/Sn alloy film plated on the second bonding layer 74 of the lid 7. While in the embodiment the bonding material 12 is layered on the second bonding layer 74 of the lid 7, it is also possible to layer the bonding material 12 on the first bonding layer 48 of the base 4.

The crystal resonator plate 2 is a Z-plate quartz crystal into which a crystal blank (not shown) that is an anisotropic crystal plate is formed by wet etching.

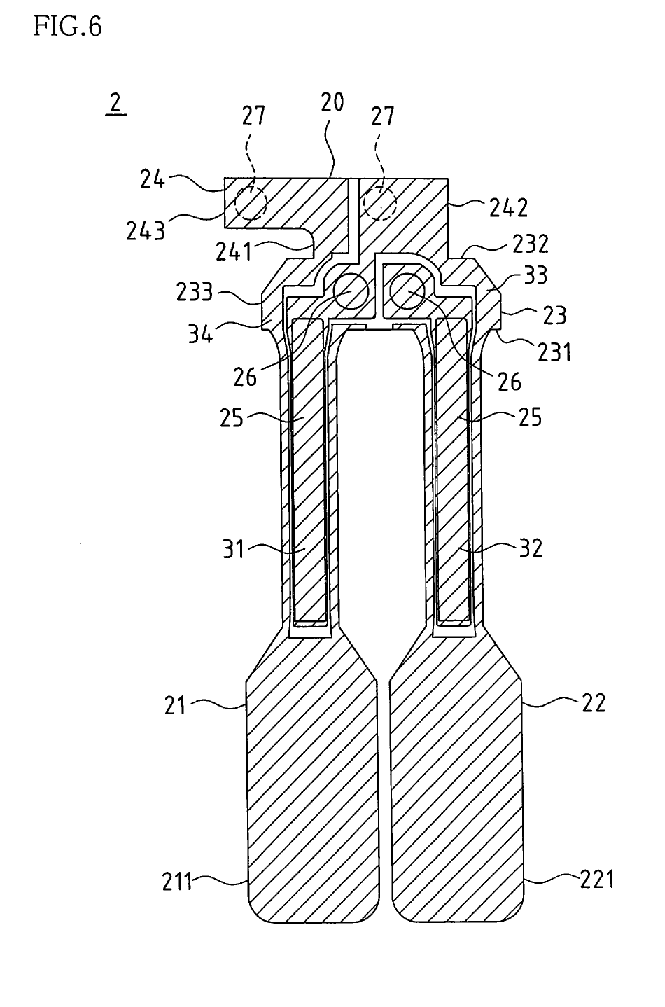

As shown in FIG. 6, the crystal resonator plate 2 includes piezoelectric resonator blank 20. The piezoelectric resonator blank 20 includes two leg portions 21 and 22 as vibrating portions, a base portion 23, and a bonding portion 24 to be bonded with the electrode pads 51 and 52 of the base 4. The two leg portions 21 and 22 project from the one end face 231 of the base portion 23. The bonding portion 24 projects from the other end face 232 of the base portion 23.

As shown in FIG. 6, the base portion 23 is bilaterally symmetrical in plan view. The base portion 23 has a side face 233 having one end face 231 side portion and the other end face 232 side portion. The one end face 231 side portion has the same width as the width of the one end face 231, while the other end face 232 side portion gradually diminishes in width toward the other end face 232 side.

As shown in FIG. 6, the two leg portions 21 and 22 project from the one end face 231 of the base portion 23 in the same direction. Distal end portions 211 and 221 of the two leg portions 21 and 22 have large widths than the widths of the other portions of the leg portions 21 and 22 (the wideness in width being in the direction perpendicular to the projecting direction). Each of the distal end portions 211 and 221 has round distal corners. Both principal surfaces of each of the two leg portions 21 and 22 have groove portions 25 for the betterment of the CI value.

As shown in FIG. 6, the bonding portion 24 projects from a center portion of the other end face 232 of the base portion 23 in the width direction. The bonding portion 24 includes a shorter side portion 241 and a longer side portion 242. The shorter side portion 241 projects perpendicular to the other end face 232 of the base portion 23 in plan view. The longer side portion 242 is connected to an end portion of the shorter side portion 241 and folded at the end portion of the shorter side portion 241 at a right angle in plan view. The longer side portion 242 then extends in the width direction of the base portion 23. The bonding portion 24 has a distal end portion 243 oriented in the width direction of the base portion 23. That is, the bonding portion 24 has an L shape in plan view. The bonding portion 24 also has bonding points 27 to be coupled to the electrode pads 51 and 52 of the base 4 via the conductive bump 13.

The crystal resonator plate 2 thus configured includes first and second driving electrodes 31 and 32 that have different potentials, and extraction electrodes 33 and 34 respectively extended from the first and second driving electrodes 31 and 32 to electrically couple the first and second driving electrodes 31 and 32 to the electrode pads 51 and 52 of the base 4.

Parts of the first and second driving electrodes 31 and 32 are disposed inside the groove portions 25 of the leg portions 21 and 22. This minimizes vibration loss of the leg portions 21 and 22 even if the crystal resonator plate 2 is downsized, thus minimizing the CI value.

First driving electrodes 31 are disposed at both principal surfaces of one leg portion 21, at both side faces of the other leg portion 22, and at both principal surfaces of the distal end portion 221. Similarly, second driving electrodes 32 are disposed at both principal surfaces of the other leg portion 22, at both side faces of one leg portion 21, and at both principal surfaces of the distal end portion 211.

The extraction electrodes 33 and 34 are disposed on the base portion 23 and the bonding portion 24. The extraction electrode 33 on the base portion 23 couples the first driving electrodes 31 on both principal surfaces of one leg portion 21 to both side faces of the other leg portion 22 and to the first driving electrodes 31 on both principal surfaces of the distal end portion 221. The extraction electrode 34 on the base portion 23 couples the second driving electrodes 32 on both principal surfaces of the other leg portion 22 to both side faces of one leg portion 21 and to the second driving electrodes 32 on both principal surfaces of the distal end portion 211.

The base portion 23 has two through holes 26 passing through both principal surfaces of the piezoelectric resonator blank 20. The through holes 26 are filled with conducting material. The extraction electrodes 33 and 34 are extended between both principal surfaces of the base portion 23 via the through holes 26.

As shown in FIG. 1, in the crystal resonator 1 thus configured, the bonding portion 24 of the crystal resonator plate 2 is electrically and mechanically bonded by ultrasonic bonding of FCB to the pedestal portion 46 on the one principal surface 42 of the base 4 via the conductive bump 13. The bonding electrically and mechanically bonds the driving electrodes 31 and 32 of the crystal resonator plate 2 to the electrode pads 51 and 52 of the base 4 via the extraction electrodes 33 and 34 and the conductive bump 13. Thus, the crystal resonator plate 2 is mounted on the base 4. Then, the lid 7 is temporarily bonded by FCB to the base 4 on which the crystal resonator plate 2 is mounted. Then, the resulting product is heated in a vacuum atmosphere to melt the bonding material 12, the first bonding layer 48, and the second bonding layer 74. This causes the first bonding layer 48 of the base 4 to be bonded to the second bonding layer 74 of the lid 7 via the bonding material 12, thus producing the crystal resonator 1 that hermetically encloses the crystal resonator plate 2. The conductive bump 13 used is a bump plating made of a non-liquid member.

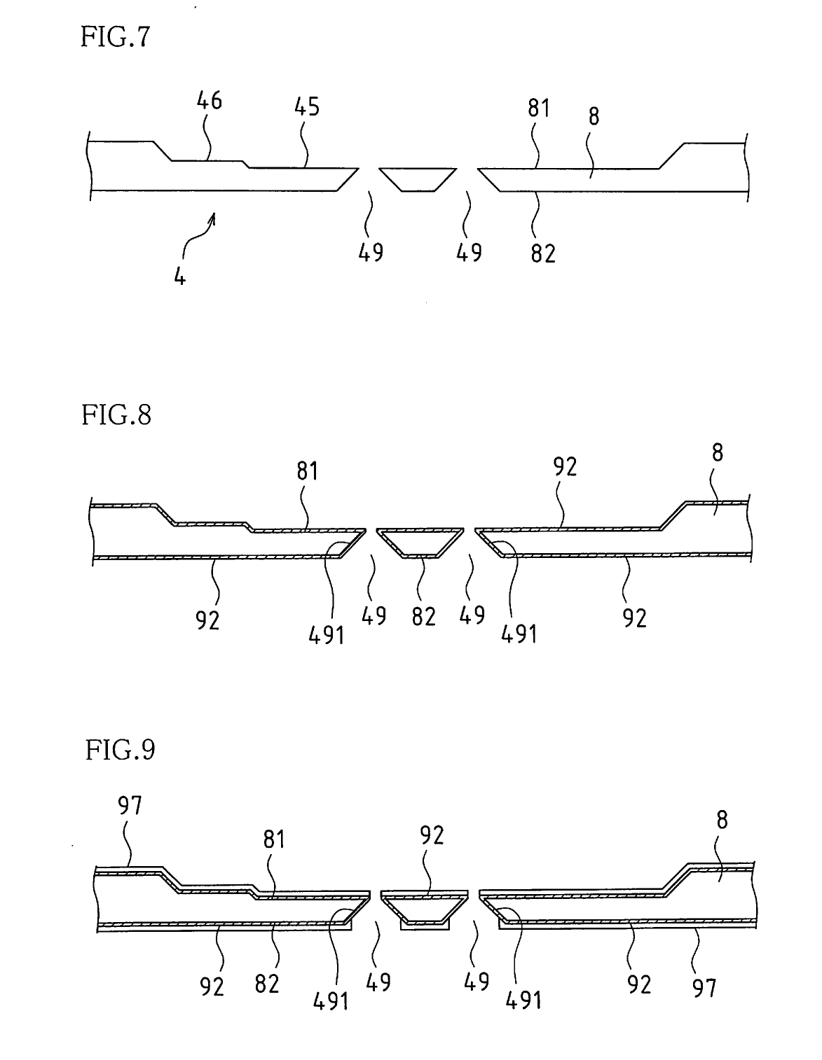

Next, a method for producing the crystal resonator 1 and the base 4 will be described below by referring to FIGS. 7 to 28.

As shown in FIG. 7, both principal surfaces 81 and 82 of a wafer 8 made of glass material are etched by wet etching using photolithography to form a plurality of bases 4 (base forming step). FIG. 7 shows one of the bases 4 formed by etching of both principal surfaces 81 and 82 of the wafer 8, and the base 4 has a cavity 45, a pedestal portion 46, and through holes 49. The pedestal portion 46, the cavity 45, the through holes 49, and other members of the base 4 may be formed by dry etching or mechanical processing such as a sandblast method.

After the base forming step, a Ti layer made of Ti is formed on the wafer 8 (including both principal surfaces 81 and 82 and the internal surfaces 491 of the through holes 49) by sputtering. After the Ti layer formation, a Cu layer made of Cu is layered on the Ti layer by sputtering, thus forming a first metal layer 92 as shown in FIG. 8 (metal layer forming step). The formed first metal layer 92 serves as the seed film made of the Ti film and the Cu film to constitute the electrode pads 51 and 52 and the wiring pattern 55 of the base 4 shown in FIG. 1.

After the metal layer forming step, a resist is applied on the first metal layer 92 by dip-coating, thus forming a new positive resist layer 97 (resist layer forming step). Then exposure and development by photolithography are carried out with respect to parts of the positive resist layer 97 formed on the open end portion of the through holes 49 of the wafer 8 at the side of the one principal surface 81, thus carrying out pattern formation with respect to the internal surfaces of the through holes 49 as shown in FIG. 9 (pattern forming step).

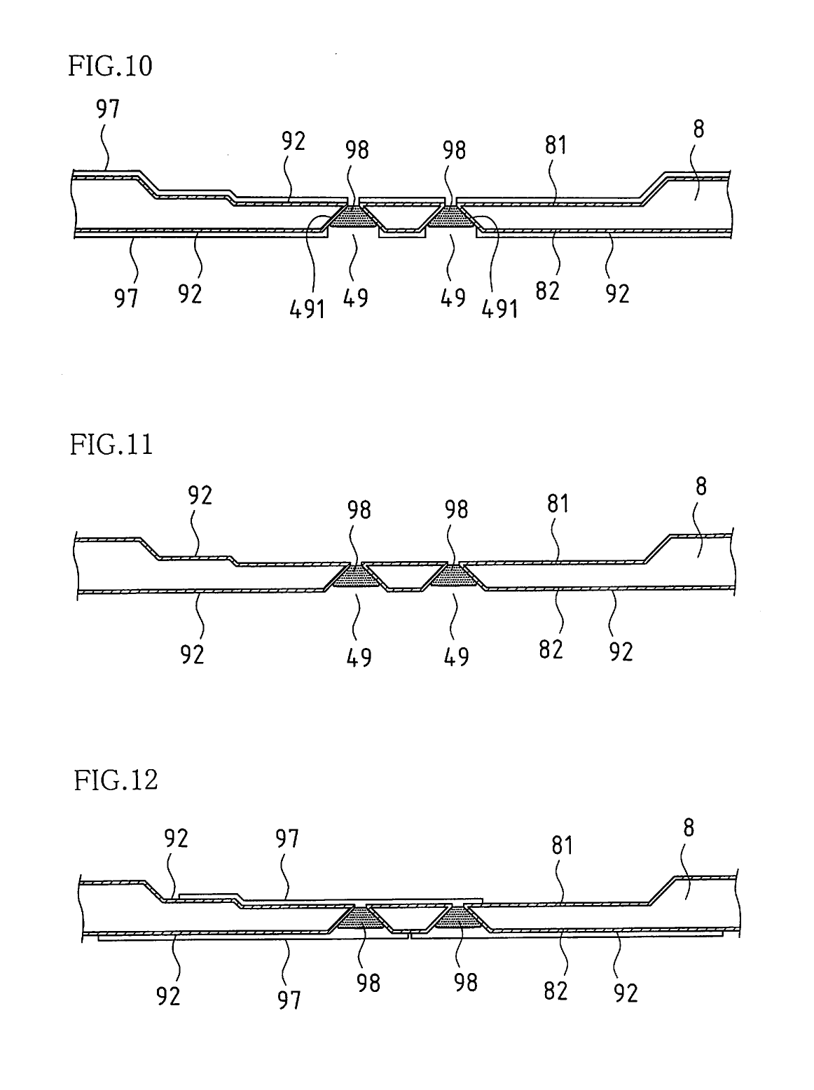

After the pattern forming step, Cu electrolytic plating is carried out with respect to the first metal layer 92 (seed film) exposed at the internal surfaces 491 of the through holes 49, thus plating an infill layer 98 made of Cu as shown in FIG. 10 (filling step).

After the filling step, the positive resist layer 97 is delaminated as shown in FIG. 11 (resist delaminatioin step).

After the resist delaminatioin step, a resist is applied on the first metal layer 92 and the infill layer 98 by dip-coating, thus forming a new positive resist layer 97 (second resist layer forming step). Then exposure and development are carried out with respect to the positive resist layer except for parts of the positive resist layer corresponding to the to-be-formed electrode pads 51 and 52 and the wiring pattern 55, thus carrying out pattern formation of the electrode pads 51 and 52, the wiring pattern 55, and the outline of the base 4 shown in FIG. 1 (second pattern forming step shown in FIG. 12).

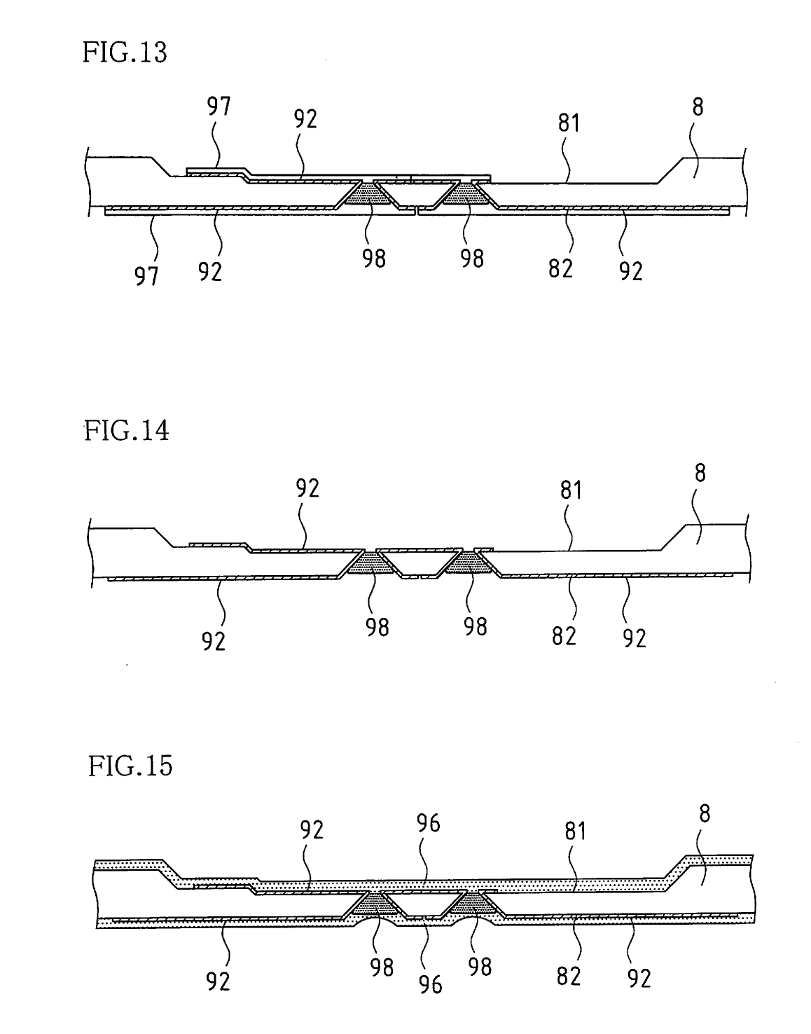

After the second pattern forming step, the exposed first metal layer 92 is removed by metal etching (metal etching step shown in FIG. 13).

After the metal etching step, the positive resist layer 97 is delaminated as shown in FIG. 14 (second resist delaminatioin step).

After the second resist delaminatioin step, a photosensitive resin material is applied on the first metal layer 92, the infill layer 98, and both principal surfaces 81 and 82 of the exposed wafer 8 by dip-coating, thus forming a resin layer 96 (resin layer forming step of FIG. 15).

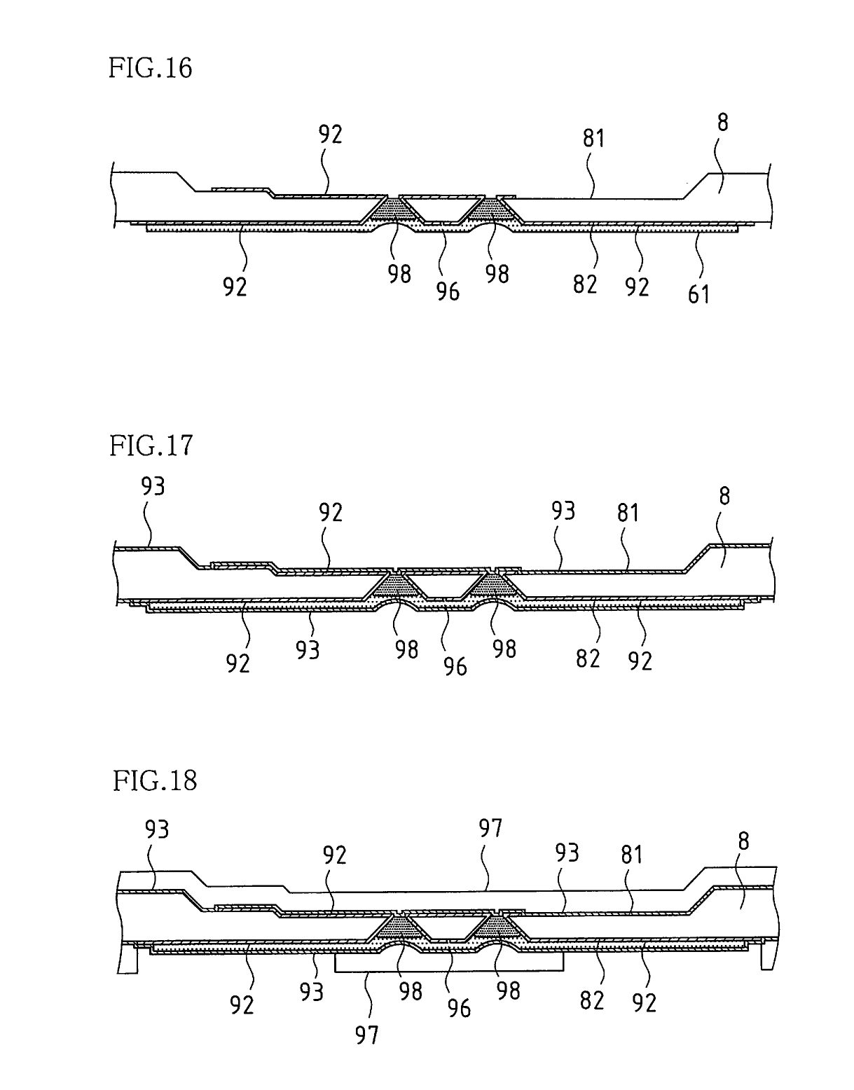

After the resin layer forming step, exposure and development by photolithography are carried out with respect to the resin layer 96 except for parts of the resin layer 96 corresponding to the to-be-formed resin pattern 61 that seals the open end portions of the through holes 49 at the side of the other end opening face 493, thus forming the resin pattern 61 as shown in FIG. 16 (resin pattern forming step).

After the resin pattern forming step, a Ti layer made of Ti is formed by sputtering on the exposed first metal layer 92 and resin layer 96 and the exposed both principal surfaces 81 and 82 of the wafer 8 as shown in FIG. 17. After the Ti layer formation, a Au layer is layered on the Ti layer by sputtering, thus forming a second metal layer 93 (second metal layer forming step). The formed second metal layer 93 serves as the sputtering film made of the Ti film and the Au film to constitute the first bonding layer 48, and as the seed film made of the Ti film and the Au film to constitute the electrode pads 51 and 52, the external terminal electrodes 53 and 54, and the wiring pattern 55 shown in FIG. 1.

After the second metal layer forming step, a resist is applied on the second metal layer 93 by dip-coating, thus forming a new positive resist layer 97 (third resist layer forming step). Then exposure and development by photolithography are carried out with respect to parts of the positive resist layer 97 corresponding to the to-be-formed external terminal electrodes 53 and 54 of the base 4, thus forming a pattern of the external terminal electrodes 53 and 54 of the base 4 as shown in FIG. 1 (third pattern forming step shown in FIG. 18).

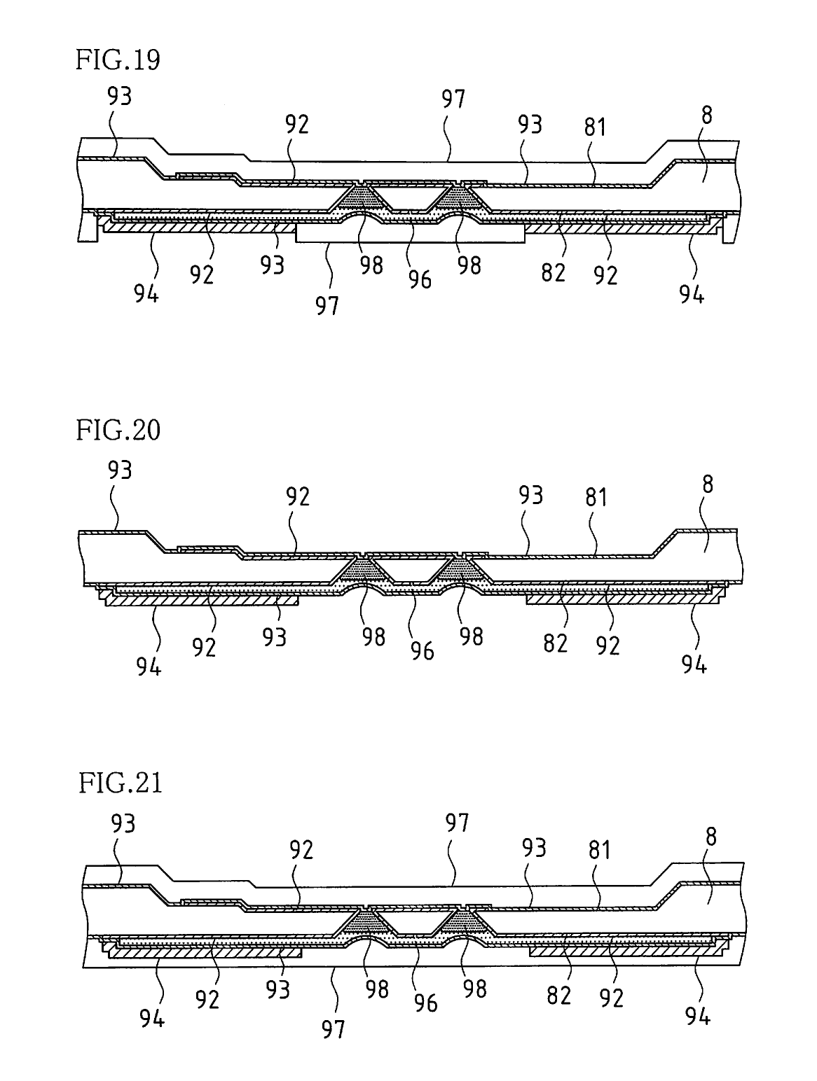

After the third pattern forming step, a first plated layer 94 made of Ni is plated on the exposed second metal layer 93 as shown in FIG. 19 (first plate forming process). The formed first plated layer 94 serves as the first plated film of the Ni film on the external terminal electrodes 53 and 54 of the base 4 (see reference numeral 94 in FIG. 1).

After the first plate forming process, the positive resist layer 97 is delaminated (third resist delaminatioin step shown in FIG. 20).

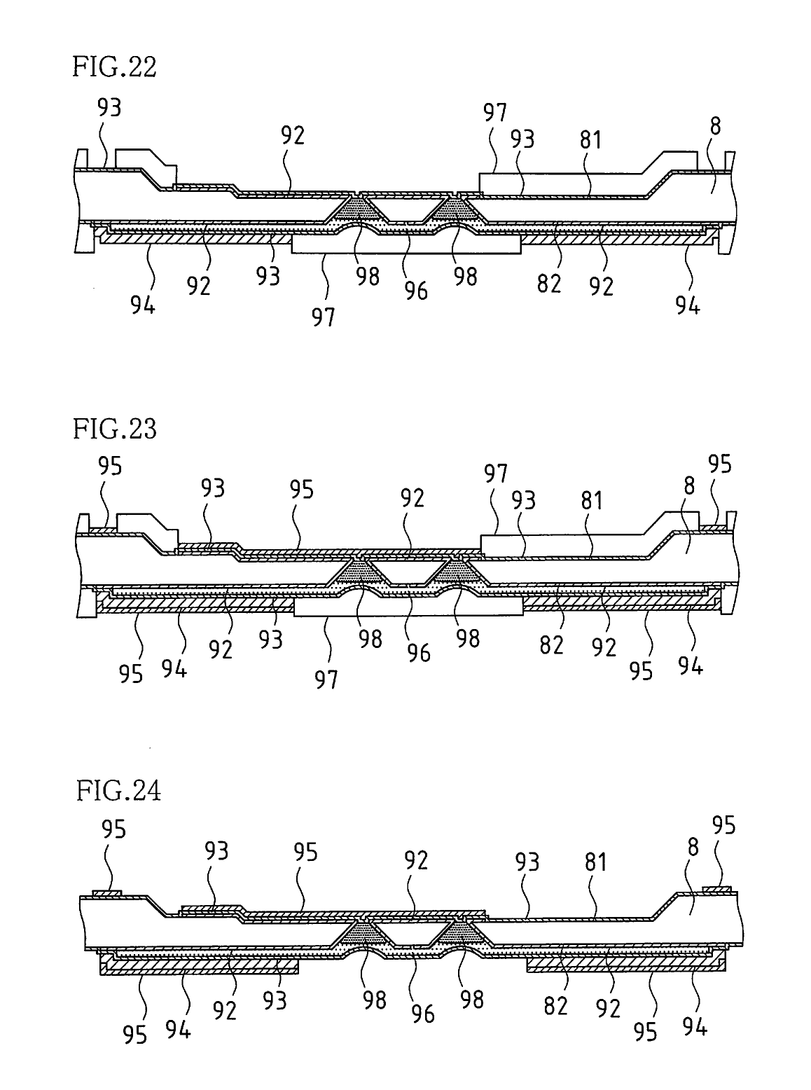

After the third resist delaminatioin step, a resist is applied on the exposed second metal layer 93 and first plated layer 94 by dip-coating, thus forming a new positive resist layer 97 (fourth resist layer forming step shown in FIG. 21). Then exposure and development by photolithography are carried out with respect to parts of the positive resist layer 97 corresponding to the to-be-formed first bonding layer 48, electrode pads 51 and 52, external terminal electrodes 53 and 54, and wiring pattern 55 of the base 4, thus forming a pattern of the first bonding layer 48, the electrode pads 51 and 52, the external terminal electrodes 53 and 54, and the wiring pattern 55 of the base 4 as shown in FIG. 1 (fourth pattern forming step shown in FIG. 22).

After the fourth pattern forming step, a second plated layer 95 made of Au is plated on the exposed second metal layer 93 and first plated layer 94 as shown in FIG. 23 (second plate forming step). The formed second plated layer 95 serves as the plated film made of the Au film to constitute the first bonding layer 48, the electrode pads 51 and 52, the external terminal electrodes 53 and 54, and the wiring pattern 55 of the base 4 as shown in FIG. 1.

After the second plate forming step, the positive resist layer 97 is delaminated as shown in FIG. 24 (fourth resist delaminatioin step).

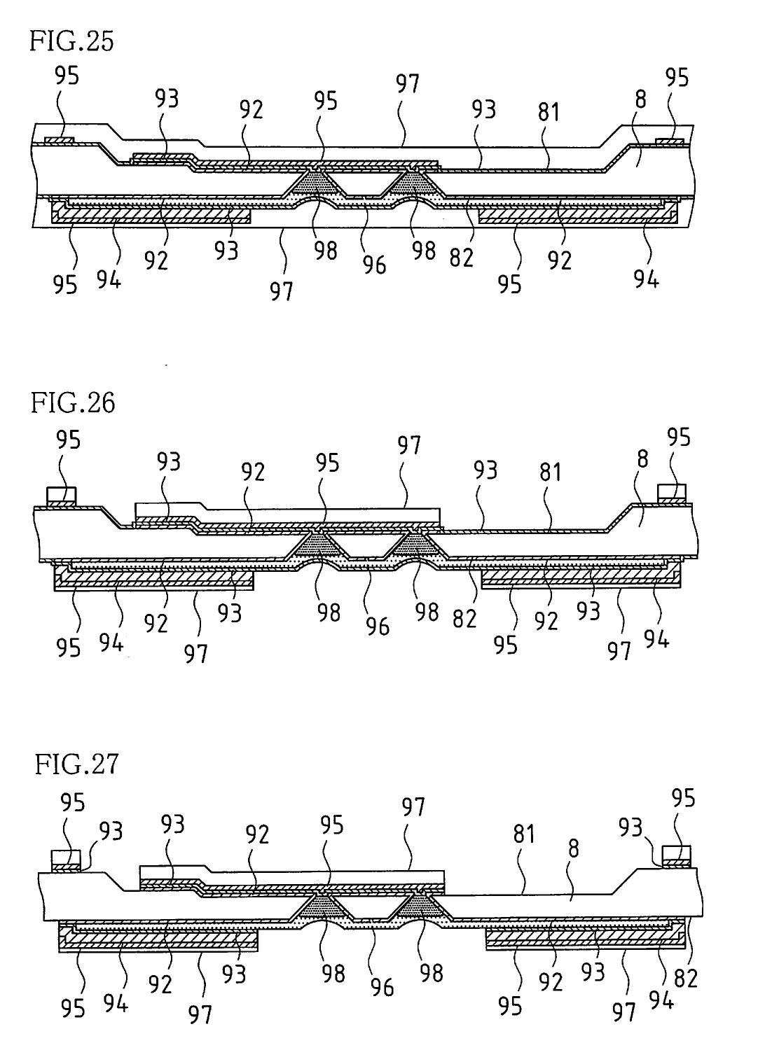

After the fourth resist delaminatioin step, a resist is applied on the exposed second metal layer 93 and second plated layer 95 by dip-coating, thus forming a new positive resist layer 97 (fifth resist layer forming step shown in FIG. 25). Then exposure and development by photolithography are carried out with respect to the positive resist layer 97 except for parts of the positive resist layer 97 corresponding to the to-be-formed first bonding layer 48, electrode pads 51 and 52, external terminal electrodes 53 and 54, and wiring pattern 55 of the base 4 as shown in FIG. 26, thus forming a pattern of the first bonding layer 48, the electrode pads 51 and 52, the external terminal electrodes 53 and 54, the wiring pattern 55 of the base 4, and the outline of the base 4 as shown in FIG. 1 (fifth pattern forming step shown in FIG. 22).

After the fifth pattern forming step, the exposed second metal layer 93 is delaminated by metal etching as shown in FIG. 27 (second metal etching step).

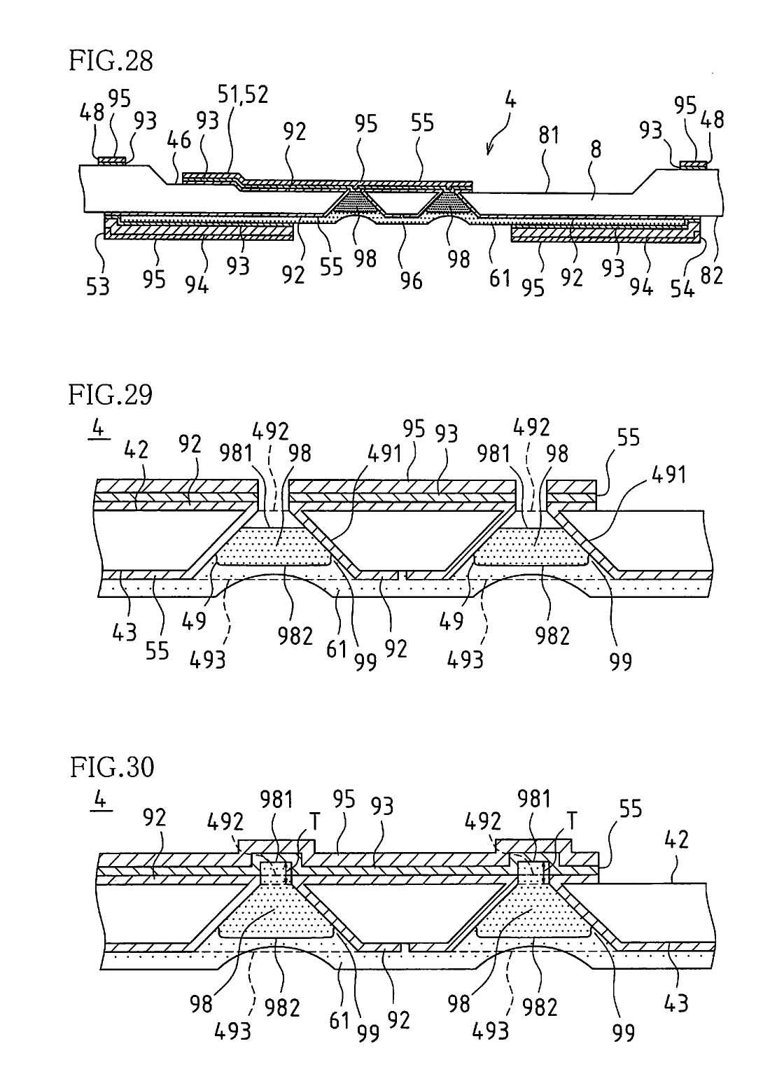

After the second metal etching step, the positive resist layer 97 is delaminated, thus forming a plurality of bases 4 on the wafer 8 as shown in FIG. 28 (fifth resist delaminatioin step).

After the fifth resist delaminatioin step, the plurality of bases 4 are divided into individual bases 4 (base dividing step), thus producing the plurality of bases 4 shown in FIG. 28.

The crystal resonator plate 2 shown in FIG. 6 is disposed on the base 4 shown in FIG. 28. The crystal resonator plate 2 is electrically and mechanically bonded to the base 4 via the conductive bump 13 by ultrasonic bonding of FCB, thus mounting the crystal resonator plate 2 on the base 4. In another step, the bonding material 12 is layered on the second bonding layer 74 of the lid 7 shown in FIG. 5. Then the lid 7 is disposed on the base 4 on which the crystal resonator plate 2 is mounted. The first bonding layer 48 of the base 4 and the second bonding layer 74 of the lid 7 are electrically and mechanically bonded to each other via the bonding material 12 by ultrasonic bonding of FCB. Thus, the crystal resonator 1 shown in FIG. 1 is produced.

In the above-described production process, the step of forming the through holes 49 in the base forming step corresponds to the through hole forming step of the present invention. The step of forming the first metal layer 92 of the seed film on the internal surfaces 491 of the through holes 49 after the metal layer forming step corresponds to the seed film forming step of the present invention. In the filling step, the step of Cu electrolytic plating on the exposed first metal layer 92 (seed film) at the internal surfaces 491 of the through holes 49 corresponds to the plating step of the present invention. The step of forming the resin pattern 61 and sealing the open end portion at the other end opening face 493 side of the through holes 49 with the resin pattern 61, after the resin layer forming step and the resin pattern forming step, corresponds to the sealing step of the present invention.

With the crystal resonator 1 according to the above-described embodiment, the resin pattern 61, which seals the open end portions of the through holes 49 at the side of the other end opening faces 493 and which contacts the other end face 982 of the infill layer 98, minimizes detachment and dropping of the conducting materials (infill layers 98) filling the through holes 49 out of the through holes 49. This minimizes degradation of air tightness in the internal space 11 of the crystal resonator 1.

In the crystal resonator 1 according to this embodiment, as shown in FIG. 4, the resin pattern 61 is disposed on the open end portions of the through holes 49 at the side of the other end opening faces 493 to prevent external exposure, outside the crystal resonator 1, of a boundary S between the seed film (see reference numeral 92 in FIG. 4) inside the through hole 49 and the infill layer 98. This prevents a brazing filler metal associated with bonding of the crystal resonator 1 to a printed circuit board from entering the internal space 11 through the boundary S of the seed film and the infill layer 98. This minimizes degradation of the driving electrodes 31 and 32 and the extraction electrodes 33 and 34 of the crystal resonator plate 2, which would otherwise be caused by erosion of the brazing filler metal at the time of bonding of the crystal resonator 1 to the printed circuit board.

In the crystal resonator 1 according to this embodiment, the infill layer 98 prevents entrance of gas into the internal space 11, when such gas occurs from the resin pattern 61 by the influence of heat associated with mounting of the crystal resonator 1 on the printed circuit board.

In the crystal resonator 1 according to this embodiment, the infill layer 98 includes a Cu plated layer plated on the seed film (see reference numeral 92 in FIG. 1) on the internal surface of each through hole 49. This, however, should not be construed as limiting the infill layer 98; any other configuration is possible insofar as the through hole 49 is filled with a conducting material. For example, the infill layer 98 may be a metal paste (a resin material paste with a conductive filler added thereto) filling the through hole 49.

In the crystal resonator 1 according to this embodiment, as shown in FIG. 4, the one end face 981 of the infill layer 98 at the side of the one principal surface 42 of the base 4 is flush with the one principal surface 42 of the base 4. This, however, is a preferred example and should not be construed in a limiting sense. Any other configuration of the infill layer 98 is possible insofar as the through holes 49 are sealed. As shown in FIG. 29, the one end face 981 of the infill layer 98 may be disposed below the one principal surface 42 of the base 4. As shown in FIG. 30, the one end face 981 of the infill layer 98 may be disposed above the one principal surface 42 of the base 4. The one end face 981 of the infill layer 98 may project from the one principal surface 42 of the base 4. In the configuration shown in FIG. 30, a projecting portion (a portion projecting from the one principal surface 42 of the base 4) of the infill layer 98 preferably has a thickness T of equal to or less than 2 μm so as to avoid contact of the crystal resonator plate 2 with the plated film constituting the wiring pattern 55 on the infill layer 98 (see reference numeral 95 in FIG. 30).

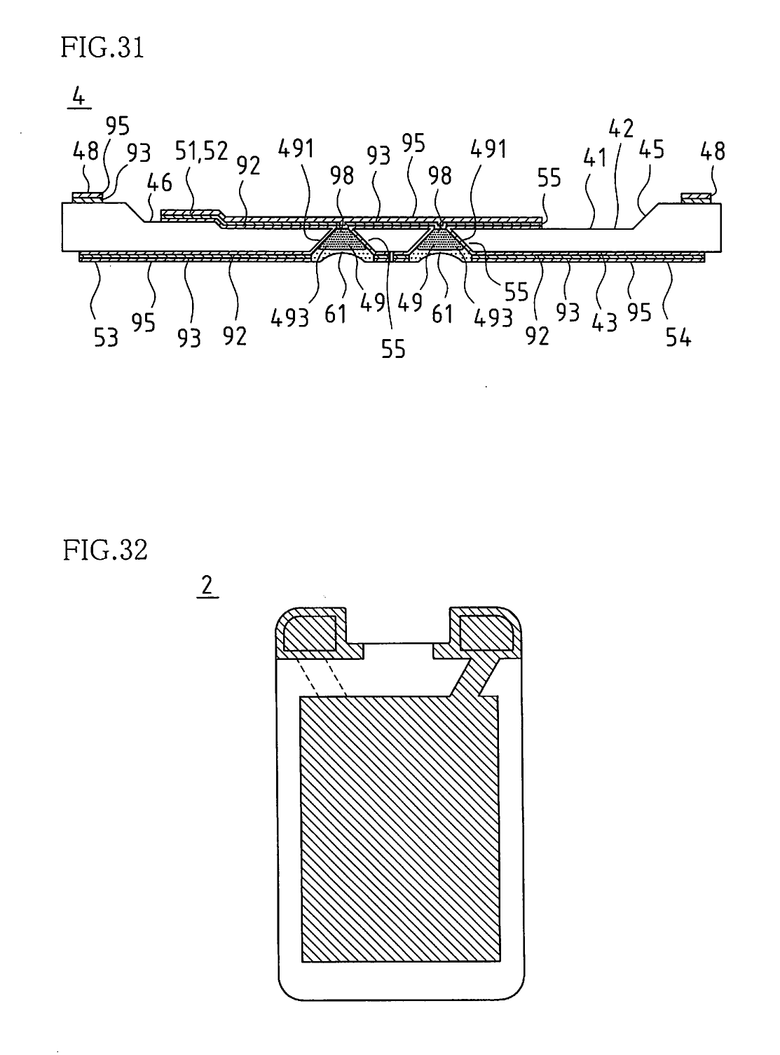

In the crystal resonator 1 according to this embodiment, the resin pattern 61, which seals the open end portions of the through holes 49 at the side of the other end opening faces 493, is formed approximately over the entire surface of the other principal surface 43, except its outer periphery portion. This, however, is a preferred example and should not be construed in a limiting sense. For example, as shown in FIG. 31, a resin pattern may be formed only on the open end portions of the through holes 49 at the side of the other end opening faces 493. This ensures a prevention effect of dropping of the conducting material (constituent material of the infill layer 98) filling each through hole 49. In the configuration shown in FIG. 31, the external terminal electrodes 53 and 54 include a seed film (see reference numeral 93 in FIG. 1) and a plated film (see reference numeral 95 in FIG. 31). The seed film is made of a Ti film and a Au film and disposed on the wiring pattern 55 (see reference numeral 92 in FIG. 1) on the other principal surface 43 of the base 4. The plated film (see reference numeral 95 in FIG. 31) is made of a Au film and disposed on the seed film.

In the crystal resonator 1 according to this embodiment, the electrode pads 51 and 52 and the wiring pattern 55 include the first seed film (see reference numeral 92 in FIG. 1), the second seed film (see reference numeral 93 in FIG. 1), and the plated film (see reference numeral 95 in FIG. 1). The first seed film is made of a Ti film and a Cu film and disposed on the substrate of the base 4. The second seed film is made of a Ti film and a Au film and disposed on the first seed film. The plated film is made of a Au film plated on the second seed film. This, however, should not be construed as limiting the electrode configuration of the electrode pads 51 and 52 and the wiring pattern 55. For example, the electrode pads 51 and 52 and the wiring pattern 55 may be without the intermediation of the seed film made of the Ti film and the Cu film; the seed film made of the Ti film and the Au film may be formed directly on the substrate of the base 4, and the Au film may be plated on this seed film. That is, the seed film of the wiring pattern 55 on the internal surfaces 491 of the through holes 49 may be made of the Ti film and the Au film. In the case where the seed film on the internal surfaces 491 of the through holes 49 is made of the Ti film and the Au film in the above manner, the infill layer 98 plated on the seed film of the wiring pattern 55 on the internal surfaces 491 of the through holes 49 is preferably a Au/Sn plated layer. This improves the strength of adhesion between the infill layer 98 and the seed film of the wiring pattern 55 on the internal surface 491.

In the base 4 of the crystal resonator 1 according to the embodiment, the first bonding layer 48 includes: the sputtering film (see reference numeral 93 in FIG. 1) made of a Ti film and a Au film on the substrate of the base 4 by sputtering; and the plated film (see reference numeral 95 in FIG. 1) made of a Au film plated on the sputtering film. This, however, should not be construed in a limiting sense. For example, the first bonding layer 48 may include: a sputtering film made of a Ti film and a Au film formed on the substrate of the base 4 by sputtering; a Ni plated film plated on the sputtering film; and a Au plated film plated on the Ni plated film. Disposing the Ni plated film between the sputtering film and the Au plated film in the above manner minimizes erosion of the sputtering film (Au film) by the bonding material 12 (brazing filler metal), and improves the strength of adhesion between the base 4 and the lid 7.

In the base 4 of the crystal resonator 1 according to this embodiment, the external terminal electrodes 53 and 54 include: the seed film (see reference numeral 93 in FIG. 1) made of a Ti film and a Au film and disposed on the seed film (see reference numeral 92 in FIG. 1) of the wiring pattern 55 of the other principal surface 43 of the base 4 and on the resin pattern 61; the first plated film (see reference numeral 94 in FIG. 1) made of Ni plated on the seed film; and the second plated film made of Au plated on the first plated film (see reference numeral 95 in FIG. 1). This, however, should not be construed in a limiting sense. For example, the second plated film made of Au may be disposed directly (without the intermediation of the first plated film of Ni) on the seed film (see reference numeral 93 in FIG. 1).

While in this embodiment the material used as the base 4 and the lid 7 is glass, the base 4 and the lid 7 will not be limited to glass. For example, it is also possible to use a quartz crystal.

While in this embodiment Au/Sn is mainly used as the bonding material 12, the bonding material 12 will not be particularly limited insofar as the base 4 and the lid 7 are bonded to one another. For example, it is also possible to use Sn alloy brazing filler metal of Cu/Sn or the like.

While in this embodiment the crystal resonator 1 uses the tuning-fork crystal resonator plate 2 shown in FIG. 6 as the crystal resonator plate, it is also possible to use an AT-cut crystal resonator plate 2 as shown in FIG. 32. In the crystal resonator 1 with the AT-cut crystal resonator plate 2, electrodes are formed on the base 4 in conformity with the AT-cut crystal resonator plate 2. Regarding the configuration of the present invention, however, the above configuration is similar to that of the above embodiment, providing similar advantageous effects.

The base 4 according to this embodiment may include an IC chip in addition to the crystal resonator plate 2, thus implementing an oscillator. Mounting an IC chip on the base 4 involves formation of electrodes on the base 4 in conformity of the electrode configuration of the IC chip.

The present invention can be embodied and practiced in other different forms without departing from the spirit and essential characteristics of the present invention. Therefore, the above-described embodiments are considered in all respects as illustrative and not restrictive. The scope of the invention is indicated by the appended claims rather than by the foregoing description. All variations and modifications falling within the equivalency range of the appended claims are intended to be embraced therein.

### REFERENCE SIGNS LIST

1 Crystal resonator
11 Internal space
12 Bonding material
13 Conductive bump
2 Crystal resonator plate (electronic component element)
20 Piezoelectric resonator blank
21, 22 Leg portion
211, 221 Distal end portion
23 Base portion
231 One end face
232 The other end face
233 Side face
24 Bonding portion
241 Shorter side portion
242 Longer side portion
243 Distal end portion
25 Groove portion
26 Through holes
27 Bonding point
31, 32 Driving electrode
33, 34 Extraction electrodes
4 Base (an electronic component package sealing member as a first sealing member of the present invention)
41 Bottom portion
42 One principal surface
43 The other principal surface
44 Wall portion
45 Cavity
452 One end portion
46 Pedestal portion
47 Resin pattern formed area
471 Longer side
472 Shorter side
473, 474 End portions
48 First bonding layer
49 Through hole
491 Internal surface
492 One end opening face
493 The other end opening face
51, 52 Electrode pad
53, 54 External terminal electrode
55 Wiring pattern
551 Periphery portion
552 Area
61 Resin pattern
7 Lid (second sealing member)
71 Top portion
72 One principal surface
73 Wall portion
731 Internal surface
732 Outer surface
733 Top face
74 Second bonding layer
8 Wafer
81, 82 Principal surfaces
92 First metal layer
93 Second metal layer
94 First plated layer
95 Second plated layer
96 Resin layer
97 Positive resist layer
98 Infill layer
981 One end face
982 The other end face
99 Gap

What is claimed is:

1. An electronic component package sealing member that can be used as a first sealing member of an electronic component package which comprises: the first sealing member having one principal surface on which an electronic component element is to be mounted; and a second sealing member opposite the first sealing member, the second sealing member hermetically enclosing an electrode of the electronic component element,
the electronic component package sealing member comprising:
a substrate constituting the electronic component package sealing member, the substrate comprising at least one through hole passing through between one principal surface and another principal surface of the substrate;
a conducting material in the at least one through hole; and
a resin material sealing an open end portion of the at least one through hole at a side of the other principal surface of the substrate.

2. The electronic component package sealing member according to claim 1, further comprising:
a seed film on an internal surface of the at least one through hole; and
a filling layer plated on a surface of the seed film, the filling layer comprising the conducting material.

3. The electronic component package sealing member according to claim 1, further comprising a resin pattern sealing the open end portion of the at least one through hole, the resin pattern comprising a photosensitive resin material.

4. An electronic component package comprising:
a first sealing member having one principal surface on which an electronic component element is to be mounted, the first sealing member is the electronic component package sealing member according to claim 1; and
a second sealing member opposite the first sealing member, the second sealing member hermetically enclosing an electrode of the electronic component element.

5. A method for producing an electronic component package sealing member that can be used as a first sealing member of an electronic component package which comprises: the first sealing member having one principal surface on which an electronic component element is to be mounted; and a second sealing member opposite the first sealing member, the second sealing member hermetically enclosing an electrode of the electronic component element,
the method comprising:
forming at least one through hole passing through between one principal surface and another principal surface of a substrate constituting the electronic component package sealing member;
filling the at least one through hole with a conducting material; and
sealing with a resin material an open end portion of the at least one through hole at a side of the other principal surface of the substrate.

6. The method according to claim 5, further comprising forming a seed film on an internal surface of the at least one through hole,
wherein the filling step comprises plating a filling layer on a surface of the seed film, the filling layer comprising the conducting material.

7. The method according to claim 5, wherein the sealing step comprises forming a resin pattern to seal the open end portion of the at least one through hole by photolithography using the resin material, the resin material having photosensitivity.
